(19) United States
(12) Patent Application Publication
(10) Pub. No.: US 2007/0262791 A1
(43) Pub. Date: Nov. 15, 2007

(54) Integrated Circuit to Store a Datum

(75) Inventor: Karl-Peter Pfefferl, Hohenkirchen-Siegertsbrunn (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munchen (DE)

(21) Appl. No.: 11/739,776

(22) Filed: Apr. 25, 2007

(30) Foreign Application Priority Data
Apr. 25, 2006 (DE) 102006019075.0

(51) Int. Cl. H03K 19/0175

(52) U.S. Cl. 326/86

(57) ABSTRACT

An integrated circuit includes a programmable circuit with a programmable element, and a storage circuit to store a storage state depending on a programming state of the programmable element of the programmable circuit unit. The storage circuit includes a first inverter circuit and a second inverter circuit. The strengthening and weakening of transistors of the first inverter circuit and of transistors of the second inverter circuit and also the repeated evaluation of the programming state of the programmable element enable the storage state stored in the storage circuit to be made resistant to corruption on account of alpha-particles or neutrons.

### CROSS REFERENCE TO RELATED APPLICATIONS

This application claims priority under 35 USC §119 to German Application No. DE 10 2006 019075.0, filed on Apr. 25, 2006, and titled “Integrated Circuit to Store a Datum,” the entire contents of which are hereby incorporated by reference.

### BACKGROUND

Fuse circuits can be used in combination with storage circuits in integrated semiconductor memory devices, for example in a DRAM (Dynamic Random Access Memory) semiconductor memory devices (for example, for the activation of redundant word and bit lines of a memory cell array). The fuse circuit includes a programmable element, such as a fusible link, that registers a programmable state of “0” when the fusible link is not severed and a programmable state of “1” when the fusible link is severed.

A fuse circuit can be arranged, for example, on a memory chip and surrounded by a housing composed of a plastic material. Due to alpha-particles that impinge on the memory chip proceeding from the plastic material of the housing, charge carriers in the material of the memory chip can be torn from their bonds. This gives rise, on the chip, to low-impedance connections between a conductor track and a substrate of the chip, which is generally charged to a ground potential. A high potential on the conductor track is conducted away through the resultant conductor track to the substrate. A storage state that was buffer-stored in the storage circuit can be corrupted by such a discharge process.

In addition, the state of the storage circuit can be influenced by neutrons that likewise generate charge carriers that establish a conductive connection between a conductor track and the substrate. Consequently, the influence of neutrons can also have the effect that the output terminal of the storage circuit drives an inaccurate datum value (e.g., a “1” state instead of a “0” state in the case of a non-blown fuse of the fuse circuit, or drives a “0” state instead of a “1” state in the case of a blown fuse of the fuse circuit). The change in state at the output terminal of the storage circuit can lead to a malfunction of the semiconductor memory device that persists until the voltage supply is switched off and switched on again, since the state of the fuse is evaluated anew as a result of the switching on of the voltage supply.

### SUMMARY

An integrated circuit and corresponding method of operating an integrated circuit are described herein. The integrated circuit comprises a programmable circuit configured to be programmed into a selected programmable state and to generate a programming state signal that is dependent upon the selected programmable state, and a storage circuit configured to receive the programming state signal from the programmable circuit, to store a first storage state or a second storage state depending upon the programming state signal received from the programmable circuit, and to generate an output signal that is dependent upon the stored storage state. The storage circuit comprises a first inverter circuit and a second inverter circuit, each of the first and second inverter circuits being connected between a first supply voltage terminal and a second supply voltage terminal, where at least one of the first inverter circuit and the second inverter circuit includes a first controllable switch connected between the first supply voltage terminal and an output terminal of the first inverter circuit and a second controllable switch connected between the output terminal of the inverter circuit and the second supply voltage terminal. The first and the second controllable switches have different conductivities in a conductive state.

The above description and still further features and advantages will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 shows an integrated circuit;

FIG. 2 shows another embodiment of an integrated circuit;

FIG. 3 shows a signal state diagram of control signals of the integrated circuit during the read-out of a storage state of the integrated circuit;

FIG. 4A shows a cross section through a transistor of the further embodiment of the integrated circuit;

FIG. 4B shows a plan view of various regions of a transistor of an embodiment of the integrated circuit; and

FIG. 5 shows an integrated semiconductor memory comprising an integrated circuit.

### DETAILED DESCRIPTION

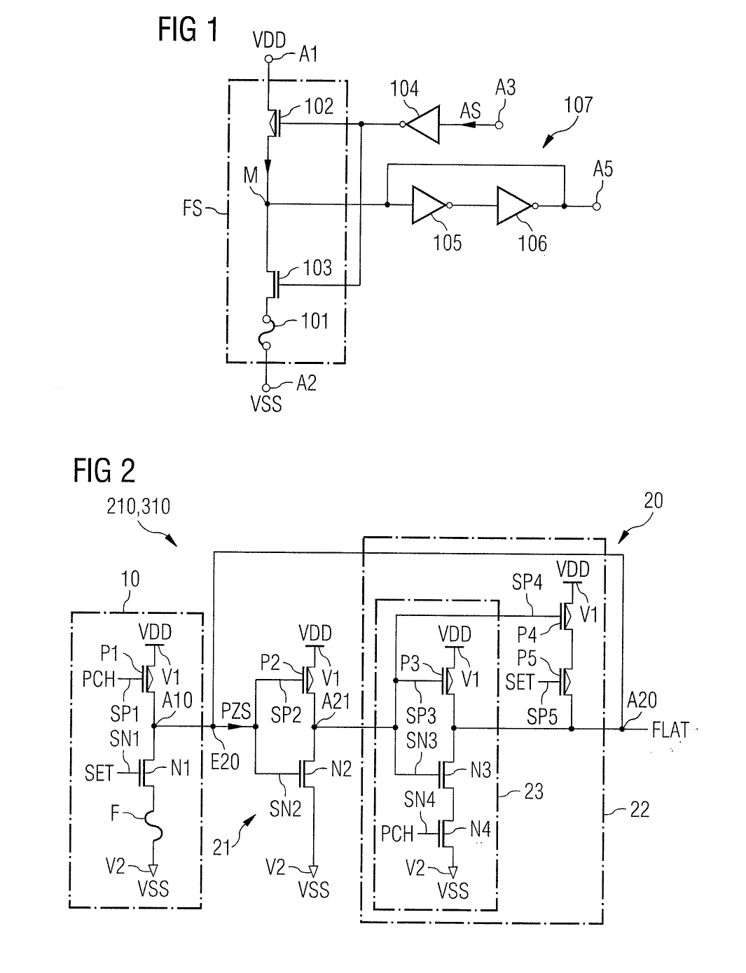

FIG. 1 shows an integrated circuit that stores a datum value. The integrated circuit comprises a fuse circuit FS comprising a p-channel transistor 102, an n-channel transistor 103 and a programmable element 101. The fuse circuit is connected between a terminal A1 for application of a supply voltage VDD and a reference voltage terminal A2 for application of a reference voltage VSS. An output terminal M of the fuse circuit is connected to a storage circuit 107 (latch). The storage circuit 107 comprises an inverter 105 and an inverter 106, an output side of the inverter 106 being coupled with feedback to an input side of the inverter 105. The state stored in the storage circuit 107 can be tapped off at an output terminal A5.

The fuse circuit is programmed with a state “1” or “0” depending on the state of the programmable element 101. If the programmable element 101, which is embodied as a fusible link, for example, is severed, the fuse circuit is programmed with the state “1”. In the non-severed state of the programmable element 101, the state “0” is programmed in the fuse circuit. In order to read out the programming state of the fuse circuit, an activation signal AS is applied to a control terminal A3. A high level of the activation signal AS is converted into a low level by the inverter 104, which low level controls the p-channel transistor 102 into the on state and the n-channel transistor 103 into the off state. As a result, firstly the output terminal M is charged to a high potential.

In order to read out the programming state of the programmable element 101, a low level of the activation signal AS is applied to the control terminal A3, by means of which the transistor 102 is controlled into the off state and the transistor 103 is controlled into the on state. If the fusible link, as illustrated in FIG. 1, is not destroyed, the charge at the output terminal M is dissipated to the reference voltage terminal A2. In this case, the output terminal M is at a low potential after the n-channel transistor 103 has been controlled into the on state. Conversely, the output terminal M remains at a high potential level if the fusible link is severed.

The high or low potential state of the output terminal M, which identifies the programming state of the fuse circuit, is buffer-stored by two inverters 105 and 106 and also the feedback of the output side of the inverter 106 to the input side of the inverter 105 in the storage circuit 107.

As noted above, the use circuits of this type in combination with a storage circuit connected downstream can be used in an integrated semiconductor memory, for example in a DRAM (Dynamic Random Access Memory) semiconductor memory, for the activation of redundant word and bit lines of a memory cell array. For this purpose, the integrated circuit shown in FIG. 1 is arranged on a memory chip surrounded by a housing composed of a plastic material. Due to alpha-particles that impinge on the memory chip proceeding from the plastic material of the housing, charge carriers in the material of the memory chip can be torn from their bonds. This gives rise, on the chip, to low-impedance connections between a conductor track and a substrate of the chip, which is generally charged to a ground potential. A high potential on the conductor track is conducted away through the resultant conductor track to the substrate. A storage state that was buffer-stored in the storage circuit 107 can be corrupted by such a discharge process.

In addition, the state of the storage circuit can be influenced by neutrons that likewise generate charge carriers that establish a conductive connection between a conductor track and the substrate. Consequently, the influence of neutrons can also have the effect that the output terminal A5 of the storage circuit 107 drives a “1” state instead of a “0” state in the case of a non-blown fuse 101, or drives a “0” state instead of a “1” state in the case of a blown fuse 101. The change in state at the output terminal A5 of the storage circuit 107 can lead to a malfunction of the semiconductor memory that persists until the voltage supply is switched off and switched on again, since the state of the fuse is evaluated anew as a result of the switching on of the voltage supply.

FIG. 2 shows an integrated circuit 210, 310 comprising a programmable circuit unit 10 and a storage circuit 20. The programmable circuit unit 10 comprises a fuse circuit including a controllable switch P1, which is embodied as a p-channel transistor, a controllable switch N1, which is embodied as an n-channel transistor, and a programmable element F, which is embodied as a fusible wire, for example. The controllable switch P1 is connected between a supply voltage terminal V1 for application of a supply voltage VDD and an output terminal A10 of the programmable circuit unit. The controllable switch N1 is connected in series with the fuse element F between the output terminal A10 of the programmable circuit unit and a supply voltage terminal V2 for application of a supply voltage VSS.

The output terminal A10 of the programmable circuit unit is connected to an input terminal E20 of the storage circuit 20. The storage circuit 20 comprises an inverter circuit 21 and an inverter circuit 22, which are connected between the input terminal E20 of the storage circuit 20 and an output terminal A20 of the storage circuit. The output terminal A20 is coupled with feedback to the input terminal E20.

The inverter circuit 21 comprises a controllable switch P2, which is embodied as a p-channel transistor, and a controllable switch N2, which is embodied as an n-channel transistor. The controllable switch P2 is connected between a supply voltage terminal V1 for application of a supply voltage VDD and an output terminal A21 of the inverter circuit 21. The controllable switch N2 is connected between the output terminal A21 of the inverter circuit 21 and a supply voltage terminal V2 for application of the supply voltage VSS. The control terminals SP2 of the controllable switch P2 and SN2 of the controllable switch N2 are connected to the input terminal E20 of the storage circuit 20. The output terminal A21 of the inverter circuit 21 is connected to an input side of the inverter circuit 22.

The inverter circuit 22 contains an activatable inverter 23. The activatable inverter 23 comprises a controllable switch P3, which is embodied as a p-channel transistor, a controllable switch N3, which is embodied as an n-channel transistor, and a controllable switch N4, which is embodied as an n-channel transistor. The controllable switch P3 is connected between a supply voltage terminal V1 for application of a supply voltage VDD and the output terminal A20 of the storage circuit 20. The controllable switches N3 and N4 are connected in series between the output terminal A20 of the storage circuit 20 and a supply voltage terminal V2 for application of a supply voltage VSS. The control terminals SP3 of the controllable switch P3 and SN3 of the controllable switch N3 are connected to the output terminal A21 of the inverter circuit 21.

The storage circuit 20 further comprises a controllable switch P4, which is embodied as a p-channel transistor, and a controllable switch P5, which is likewise embodied as a p-channel transistor. The two controllable switches P4 and P5 are connected in series between a supply voltage terminal V1 for application of a supply voltage VDD and the output terminal A20 of the storage circuit 20. A control terminal SP4 of the controllable switch P4 is connected to the output terminal A21 of the inverter circuit 21.

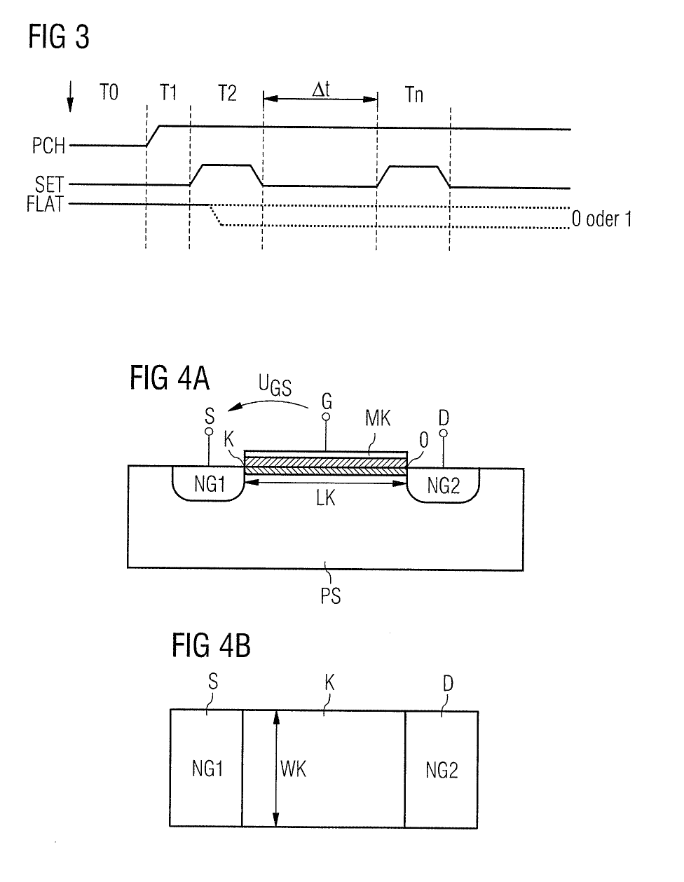

The functioning of the circuit arrangement shown in FIG. 2 is described below with reference to the signal flow diagram in FIG. 3. During the production of the integrated circuit shown in FIG. 2, a programming state “0” is stored in the programmable circuit unit by virtue of the fuse element F not being severed. The programming state “1” can be stored by virtue of the wire of the fuse element F embodied as a fusible link being severed by means of a laser beam, for example, during the production of the integrated circuit.

In order to read out the programmed-in state of the programmable circuit unit and in order to buffer-store the programming state in the storage circuit 20, the programmable circuit unit must first be initialized. During a time phase T0, control terminal SP1 of the controllable switch P1 is driven with a low level of an activation signal PCH. An activation signal SET likewise drives control terminal SN1 of the controllable switch N1 with a low level. As a result, the controllable switch P1 is in a conducting state and the controllable switch N1 is in a blocking state. The output terminal A10 is therefore charged to a high potential (“1” state) (initialization state). A programming state signal PZS, which occurs at the output terminal A10, therefore has the programming state “1”.

The input terminal E20 of the storage circuit 20 is driven by the programming state signal PZS. The programming state “1” is inverted by the inverter circuit 21, whereby the controllable switch P4 is controlled into the conducting state. The controllable switch P5 is likewise controlled into the conducting state by the low level of the activation signal SET, with the result that a storage state “1” occurs at the output terminal A20 of the storage circuit 20. The integrated circuit is now initialized for the actual read-out process of the programmable circuit unit 10.

In order to read out the programming state of the programmable element F of the programmable circuit unit 10, the activation signal PCH is subsequently applied with a high level to the control terminals SP1 of the controllable switch P1 and SN4 of the controllable switch N4. Furthermore, the activation signal SET is still present with a low level at the control terminals SN1 of the controllable switch N1 and SP5 of the controllable switch P5. The controllable switch N4 is switched into the conducting state by the high level of the activation signal PCH. The activatable inverter 23 is thus activated. At the time phase T1, therefore, the state of the programming state signal PZS generated at the output terminal A10 is buffer-stored in the storage circuit 20.

At the time phase T2, the activation signal SET is applied with a high level to the control terminal SN1 and the control terminal SP5, while the activation signal PCH retains the high level. As a result, the controllable switch N1 is controlled into the conducting state and the controllable switch P5 is controlled into the turned off state. In the case of a non-blown (non-severed) programmable element F, the charge to which the output terminal A10 was charged during the initialization process flows away to the supply voltage terminal V2 via the controllable switch N1 that has been controlled into the conducting state and the intact fusible wire. In the case of a blown (severed) programmable element F, the output terminal A10 continues to remain at the high potential to which it was charged during the initialization phase. Since the activatable inverter 23 is still active during the time phase T2, the state of the programming state signal PZS that is present at the input terminal E20 is read into the storage circuit 20 and buffer-stored there as the storage state. The output signal FLAT occurs with a high or low level at the output terminal A20 depending on the buffer-stored storage state.

FIG. 4A shows a cross section through one of the transistors of the integrated circuit from FIG. 2. Two doped regions NG1 and NG2 are embedded into a substrate PS. The doped region NG1 is connected to a terminal S, for example a source terminal of the transistor. The doped region NG2 is connected to a terminal D, for example a drain terminal of the transistor. A metallic contact MK is arranged between the two doped regions NG1 and NG2, and is connected to a control terminal G, for example the gate terminal of the transistor. The metallic contact MK is insulated from the top side of the substrate PS by an oxide layer O. A conductive channel K having a channel length LK forms between the doped regions depending on a control voltage U_{GS} present between the gate and source terminals.

FIG. 4B shows a plan view of the transistor described in FIG. 4A, where the gate terminal G, the metallic contact MK, the oxide layer O and the substrate PS are not depicted for the sake of better clarity. The conductive channel K has the width WK and is delimited or bounded by the doped region NG1 on one side and by the doped region NG2 on the other side of the conductive channel.

In the case of a p-channel transistor, the doped regions NG1 and NG2 are embodied as p-doped regions and the substrate PS is embodied as an n-doped substrate. In the case of an n-channel transistor, the doped regions are in each case embodied as n-doped regions and the substrate is embodied as a p-doped substrate. The resistance of the channel K is dependent on the channel length LK and the channel width WK. Thus, when a channel for a first transistor is shorter or wider than a channel for a second transistor, the impedance exhibited by the first transistor in the conducting state is correspondingly lower than the impedance exhibited by the second transistor.

The transistor N2 in the conducting state is provided with lower impedance (strengthening of the transistor N2) than the transistor P2 in the conducting state (weakening of the transistor P2). Furthermore, in the conducting state of the transistors P4 and P5, the series circuit comprising the transistors P4 and P5 is provided with lower impedance (strengthening of the transistors P4 and P5) than that with which the series circuit comprising the transistors N3 and N4 (weakening of the transistors N3 and N4) is embodied in the conducting state of the transistors N3 and N4.

A strengthening and weakening of transistors can be obtained, for example, by changing the channel lengths and channel widths of the transistors (i.e., as described above with reference to FIGS. 4A and 4B). A strengthening of a transistor can be achieved by reducing the channel length and/or increasing the channel width, whereas conversely a weakening of the transistor is achieved by increasing the channel length and/or reducing the channel width. It should be taken into consideration that, on account of the technology, p-channel transistors are often weaker (exhibit higher impedance) than n-channel transistors despite identical channel length and width.

As a result of the strengthening of the transistors N2, P4 and P5 and the weakening of the transistors P2, N3 and N4, the state of the output signal FLAT=1, corresponding to the initialization state at the time phase T0 and the state in the case of a severed programmable element F at the time phase T2, becomes resistant to an undesired state change due to alpha-particles or neutrons. As a result of the strengthening of the transistors N2, P4 and P5 and the weakening of the transistors P2, N3 and N4, the state of the output signal FLAT=0, corresponding to the state in the case of a non-severed programmable element F at the time phase T2, becomes more susceptible to an undesired state change on account of alpha-particles or neutrons. A corrupted state of the output signal can be corrected again, however, by repeated evaluation of the programmed-in state of the programmable element F. For this purpose, it suffices for a pulse to be applied to the activation signal SET (time phase Tn) in order to reverse the undesired state change on account of alpha-particles or neutrons that altered the state of the output signal FLAT from the state “0” to the state “1”, and thus to reestablish the state of the output signal FLAT=0 for the programmable circuit unit with a non-severed programmable element F.

The susceptibility to an undesired state change on account of alpha-particles or neutrons can be lowered overall by the strengthening of the transistors N2, P4 and P5 and the weakening of the transistors P2, N3 and N4 and the repeated evaluation of the programmable state of the programmable element F.

If the output signal FLAT at the output terminal A20 has the state “0” and the programmable element F is not severed, the output signal FLAT has the correct programming or storage state. No error has occurred in this case. The state of the storage circuit has not been corrupted on account of alpha-particle and neutron influence. If the activation signal SET is fed in with a high level at specific time intervals Δt onto the control terminals SN1 and SP5 of the transistors N1 and P5, and the control terminals SP1 and SN4 are permanently driven with a high level of the activation signal PCH, the output signal FLAT continues to remain at the state “0”.

If the output signal FLAT has the state “0” and the programmable element F is severed (blown), the storage state of the storage circuit 20 has been corrupted. In this case, the programming state of the programmable element F cannot be read out merely by driving the control terminals SN1 and SP5 with a high pulse of the activation signal SET, since a low potential is likewise present at the output terminal A10 on account of the feedback. Consequently, the initialization state would not be present at the output terminal A10. However, since the transistors N2, P4 and P5 have been strengthened relative to the transistors P2, N3 and N4, it is possible to prevent the situation in which a state change of the output signal FLAT=“1” to the state FLAT=“0” occurs as a result of alpha-particles and neutrons while the fusible wire is severed. By contrast, the state “1” of the output signal FLAT at the output terminal A20 is reliably held at the state “1” as a result of the strengthening of the transistors N2, P4 and P5 relative to the transistors P2, N3 and N4.

If the output signal FLAT has the state “1” and the programmable element F is not severed, the storage state of the storage circuit 20 has been corrupted on account of alpha-particles or neutrons. The output signal FLAT at the output terminal A20 should actually have the state “0” if the fusible wire of the programmable element F is not severed. If the control terminals SN1 and SP5 are driven by a high pulse of the activation signal SET at time intervals Δt, while the control terminals SP1 and SN4 are permanently driven by a high level of the activation signal PCH, the programming state of the programmable element F is read out again, since the output terminal A20, via the feedback, has assumed the corrupted state, in this case the high level necessary for read-out, of the output signal FLAT. As a result of driving with the high pulse of the activation signal SET, in this case the programming state of the programmable circuit unit is read out again, with the result that the output signal FLAT has the correct state “0” again after the end of the read-out process.

If the output signal FLAT has the state “1” and the programmable element F is severed, the storage state of the storage circuit 20 has not been corrupted. In this case, too, the read-out of the programming state of the programmable circuit unit 10 is only possible by driving the control terminals SN1 and SP5 with the high pulse of the activation signal SET, since the output terminal A10 has been charged, via the feedback, to a high potential state, that is to say is in the initialization state.

Providing strong transistors N2, P4 and P5 and weak transistors P2, N3 and N4 makes it possible to virtually preclude the situation in which the state of the output signal FLAT=“1” is corrupted into the state FLAT=“0” if the fusible wire of the programmable element is severed. This enables the programmable circuit unit 10 to be read merely by a high pulse on the activation signal SET, while the activation signal PCH, which drives the transistors P1 and N4, is held at a high level.

The power demand of the integrated circuit can therefore be significantly reduced by comparison with a read-out of the programmable circuit unit by the activation signal sequence applied in the time phases T0, T1 and T2. If it is assumed that a plurality of the programmable elements F are not blown, the state of the output signal FLAT would have to be subjected to charge reversal twice when carrying out the steps during the time phases T0, T1 and T2 in the case of the multiplicity of the integrated circuits. By contrast, the strengthening of the transistors N2, P4 and P5 relative to the transistors P2, N3 and N4 makes it possible for the storage state of the storage circuit to be updated merely by driving the control terminals SN1 and SP5 with a high pulse of the activation signal SET. Charge reversal of the output terminal A20 twice occurs only when the state of the storage circuit 20 has changed as a result of alpha-particles or neutrons.

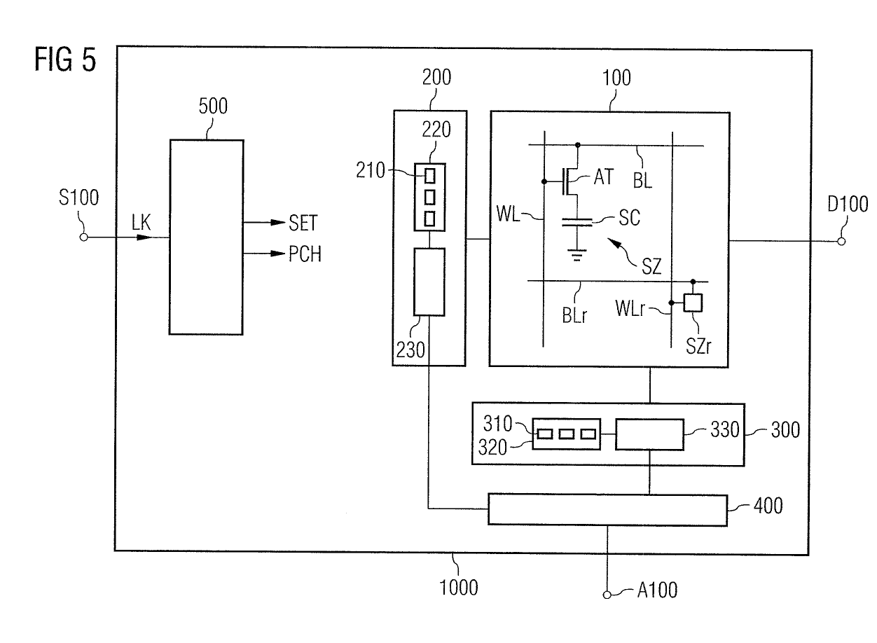

FIG. 5 shows the application of the integrated circuit illustrated in FIG. 2 in an integrated semiconductor memory 1000. The integrated semiconductor memory comprises a memory cell array 100, in which memory cells SZ are arranged at crossover points of word lines WL and bit lines BL. In the case of a DRAM memory cell SZ, the memory cell includes a selection transistor AT and a storage capacitor SC. In order to read from a memory cell SZ, an address signal is applied to an address terminal A100 and a read command LK is applied to a control terminal S100. The read command LK is evaluated by a control circuit 500. Depending on the address applied to the address terminal A100, a bit line decoder 200 and a word line decoder 300, both of which are connected to an address register 400, select one of the bit lines BL and one of the word lines WL for a read access. Consequently, the memory cell SZ arranged at the crossover point between the selected bit line and the selected word line is selected for the read access. After the read-out of the memory cell SZ, a datum appears at a data terminal D100 depending on the state of the memory cell SZ.

The bit line decoder 200 contains a storage unit 220 comprising a plurality of the integrated circuits 210. Bit line addresses of defective bit lines BL are stored in the storage circuits 20 of the integrated circuits 210. The storage unit 220 is coupled to a comparator unit 230. A bit line address applied to the address terminal A100 is compared, in the comparator unit 230, with the bit line addresses of defective bit lines that are stored in the storage unit 220.

The word line decoder 300 comprises a storage unit 320 containing a plurality of integrated circuits 310. Addresses of defective word lines are stored in the storage circuits 20 of the integrated circuits 310. The storage unit 320 is coupled to a comparator unit 330. A word line address applied to the address terminal A100 is compared, by comparator unit 330, with the word line addresses of defective word lines that are stored in the storage circuits of the integrated circuits 310.

Upon application of a bit line address identifying a defective bit line, and upon application of a word line address identifying a defective word line, a redundant word line WLr and a redundant bit line BLr, respectively, are selected instead of the defective word line and bit line and the memory cell SZr connected to said redundant word line and redundant bit line is read. The storage content of the storage circuits 20 of the integrated circuits 210 and 310 is updated by driving the integrated circuits with a high pulse of the activation signal SET at specific time intervals. This prevents malfunctions of the integrated semiconductor memory device due to alpha-particles or neutrons.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

1. An integrated circuit comprising:
a programmable circuit configured to be programmed into a selected programmable state and to generate a programming state signal that is dependent upon the selected programmable state; and
a storage circuit configured to receive the programming state signal from the programmable circuit, to store a first storage state or a second storage state depending upon the programming state signal received from the programmable circuit, and to generate an output signal that is dependent upon the stored storage state, the storage circuit comprising a first inverter circuit and a second inverter circuit, each of the first and second inverter circuits being connected between a first supply voltage terminal and a second supply voltage terminal;
wherein at least one of the first inverter circuit and the second inverter circuit includes a first controllable switch connected between the first supply voltage terminal and an output terminal of the inverter circuit and a second controllable switch connected between the output terminal of the inverter circuit and the second supply voltage terminal, and the first and the second controllable switches have different conductivities in a conductive state.

2. The integrated circuit of claim 1, wherein the output terminal of the first inverter circuit is connected to an output terminal of the storage circuit via the second inverter circuit, at least the first inverter circuit includes first and second controllable switches.

3. The integrated circuit of claim 2, wherein the first and second controllable switches of the first inverter circuit are configured such that the second controllable switch in a conducting state connects the output terminal of the first inverter circuit to the second supply voltage terminal at an impedance that is lower than an impedance at which the first controllable switch in a conducting state connects the first supply voltage terminal to the output terminal of the first inverter circuit.

4. The integrated circuit of claim 2, wherein the first controllable switch of the first inverter circuit comprises a first transistor including a control terminal that is connected to an output terminal of the programmable circuit unit and the second controllable switch of the first inverter circuit comprises a second transistor including a control terminal that is connected to the output terminal of the programmable circuit unit.

5. The integrated circuit of claim 4, wherein the second transistor of the first inverter circuit comprises an n-channel transistor.

6. The integrated circuit of claim 4, wherein the first transistor of the first inverter circuit comprises a p-channel transistor.

7. The integrated circuit of claim 4, wherein each of the first and second transistors of the first inverter circuit includes a controllable channel, the controllable channel of the first transistor has a length that is greater than a length of the second transistor, and the controllable channel of the second transistor has a width that is greater than a width of the controllable channel of the first transistor.

8. The integrated circuit of claim 1, wherein at least the second inverter circuit includes first and second controllable switches, the first inverter circuit feeds the programming state signal to the second inverter circuit, and the output terminal of the second inverter circuit comprises an output terminal of the storage circuit.

9. The integrated circuit of claim 8, wherein the first and second controllable switches of the second inverter circuit are configured such that the first controllable switch in a conducting state connects the first supply voltage terminal to the output terminal of the storage circuit at an impedance that is lower than an impedance at which the second controllable switch in a conducting state connects the output terminal of the storage circuit to the second supply voltage terminal.

10. The integrated circuit as claimed in claim 8, wherein the first and the second inverter circuits are connected in series between an input terminal of the storage circuit and the output terminal of the storage circuit, and the output terminal of the storage circuit is connected to the input terminal of the storage circuit.

11. The integrated circuit of claim 8, wherein the first controllable switch of the second inverter circuit comprises a first transistor including a control terminal connected to an output terminal of the first inverter circuit and the second controllable switch of the second inverter circuit comprises a second transistor including a control terminal connected to the output terminal of the first inverter circuit.

12. The integrated circuit of claim 11, wherein the second inverter circuit further comprises a third transistor including a control terminal, the first and third transistors of the second inverter circuit are connected in series between the first supply voltage terminal and the output terminal of the storage circuit, and the control terminal of the third transistor of the second inverter circuit is driven by an activation signal.

13. The integrated circuit of claim 11, wherein the second inverter circuit further comprises an activatable inverter including a control terminal to apply a first activation signal to activate the activatable inverter, the activatable inverter is connected between the output terminal of the first inverter circuit and the output terminal of the storage circuit.

14. The integrated circuit as claimed in claim 13, wherein the activatable inverter comprises the second transistor, a fourth transistor and a fifth transistor, the fourth transistor is connected between the first supply voltage terminal and the output terminal of the storage circuit and includes a control terminal that is connected to the output terminal of the first inverter circuit, the second transistor and the fifth transistor are connected in series between the output terminal of the storage circuit and the second supply voltage terminal, a control terminal of the second transistor is connected to the output terminal of the first inverter circuit and a control terminal of the fifth transistor is driven by an activation signal.

15. The integrated circuit of claim 14, wherein the first and third transistors of the second inverter circuit and the second and fifth transistors of the activatable inverter are configured such that, in a conducting state, the first and third transistors connect the first supply voltage terminal to the output terminal of the storage circuit at an impedance that is lower than an impedance at which the second and fifth transistors of the activatable inverter, in a conducting state, connect the output terminal of the storage circuit to the second supply voltage terminal.

16. The integrated circuit of claim 14, wherein each of the second and fifth transistors of the activatable comprises an n-channel transistor.

17. The integrated circuit as claimed in claim 12, wherein each of the first and third transistors of the second inverter circuit comprises a p-channel transistor.

18. The integrated circuit of claim 11, wherein each of the transistors includes a controllable channel, the first transistor has a length that is less than a length of the second transistor, and the first transistor has a width that is greater than a width of the channel of the second transistor.

19. The integrated circuit of claim 1, wherein the second inverter circuit includes first and second controllable switches, the output terminal of the second inverter circuit comprises an output terminal of the storage circuit, and the first and second controllable switches of the second inverter circuit are configured such that the first controllable switch in a conducting state connects the first supply voltage terminal to the output terminal of the storage circuit at an impedance that is lower than an impedance at which the second controllable switch in a conducting state connects the output terminal of the storage circuit to the second supply voltage terminal.

20. The integrated circuit of claim 1, wherein the programmable circuit unit comprises a first controllable switch, a second controllable switch and a programmable element, the first controllable switch of the programmable circuit unit is connected between the first supply voltage terminal and an output terminal of the programmable circuit unit, and the second controllable switch and the programmable element are connected in series between the output terminal of the programmable circuit unit and the second supply voltage terminal.

21. The integrated circuit of claim 20, wherein the first controllable switch of the programmable circuit unit comprises a first transistor including a control terminal that is driven by a first activation signal, and the second controllable switch of the programmable circuit unit comprises a second transistor including a control terminal that is driven by a second activation signal.

22. The integrated circuit of claim 21, wherein the first and second transistors of the programmable circuit have different conductivities.

23. The integrated circuit of claim 20, wherein the programmable element comprises a fuse circuit.

24. The integrated circuit of claim 1, further comprising:
a memory cell array comprising memory cells arranged along bit lines and word lines, wherein each of the memory cells is selectable by selection of one of the bit lines using a bit line address and by selection of one of the word lines using a word line address, and bit and word line addresses are stored in the storage circuit based upon the programming state programmed into the programmable circuit.

25. A method of operating an integrated circuit, comprising:
(a) providing an integrated circuit including a programmable circuit that includes a programmable element, a first control terminal that applies a first activation signal, a second control terminal that applies a second activation signal and an output terminal that generates a programming state signal having a first level or a second level, the integrated circuit further including a storage circuit that stores a storage state;
(b) driving the programmable circuit with the first activation signal at a first state and the second activation signal at a first state;
(c) generating the programming state signal at the first or second level at the output terminal of the programmable circuit;
(d) driving the programmable circuit with the first activation signal at a second state;
(e) storing a storage state in the storage circuit and generating an output signal at the storage circuit that corresponds with the storage state, wherein the storage state and corresponding output signal are dependent upon the level of the programming state signal generated in step (c);
(f) driving the programmable circuit with the second activation signal at a second state;
(g) generating the programming state signal at a level that is dependent upon a state of the programmable element of the programmable circuit with the programmable circuit being driven as described in step (f);
(h) storing a storage state in the storage circuit and generating an output signal at the storage circuit that corresponds with the storage state, wherein the storage state and corresponding output signal are dependent upon the level of the programming state signal generated in step (g);
(i) driving the programmable circuit with the second activation signal at the first state to store a storage state in the storage circuit that is dependent upon the level of the output signal;
(j) driving the programmable circuit with the second activation signal at the second state while the programmable circuit is also being driven with the first activation signal at the second state;
(k) generating the programming state signal at a level that is dependent upon a state of the programmable element of the programmable circuit when the programmable circuit is being driven as described in step (j); and
(l) storing a storage state in the storage circuit and generating an output signal at the storage circuit that corresponds with the storage state, wherein the storage state and corresponding output signal are dependent upon the level of the programming state signal generated in step (k).

26. The method of claim 25, wherein:
the storage circuit comprises a first control terminal to apply the first activation signal and a second control terminal to apply the second activation signal to the storage circuit to store a storage state;
the storage circuit is driven with the first activation signal at the second state when the programmable circuit is driven with the first activation signal at the second state;
the storage circuit is driven with the second activation signal at the second state when the programmable circuit is driven with the second activation signal at the second state;
the storage circuit is driven with the second activation signal at the first state when the programmable circuit is driven with the second activation signal at the first state; and
the first control signal of the storage circuit is driven with the first activation signal at the first state when the programmable circuit is driven with the first activation signal at the first state.
